(19) United States
(12) Patent Application Publication
(10) Pub. No.: US 2012/0184107 A1
(43) Pub. Date: Jul. 19, 2012

(54) SEMICONDUCTOR DEVICE MANUFACTURING METHOD

(75) Inventors: Yoshihiro Sato, Nirasaki-shi (JP); Toshihiko Shiozawa, Nirasaki-shi (JP); Tatsuo Nishita, Nirasaki-shi (JP); Yoshihiro Hirota, Nirasaki-shi (JP)

(73) Assignee: TOKYO ELECTRON LIMITED, Tokyo (JP)

(21) Appl. No.: 13/498,259

(22) PCT Filed: Sep. 29, 2010
(86) PCT No.: PCT/JP2010/066886

§ 371 Date: Mar. 26, 2012

(30) Foreign Application Priority Data
Sep. 30, 2009 (JP) 2009-227638
Sep. 16, 2010 (JP) 2010-207773

(51) Int. Cl. H01L 21/311

(52) U.S. Cl. 438/703; 257/E21.251

(57) ABSTRACT

In a semiconductor device manufacturing method, the formation of a sacrificial oxide film and removal thereof by wet etching and/or the formation of a silicon dioxide film and removal thereof by wet etching are performed. In the process for manufacturing a semiconductor device, the formation of the sacrificial oxide film and/or the silicon dioxide film is performed within a processing chamber of a plasma processing apparatus using a plasma in which O(¹D₂) radicals produced using a processing gas that contains oxygen are dominant.

### FIELD OF THE INVENTION

The present invention relates to a semiconductor device manufacturing method that can be applied to manufacture of, e.g., a transistor or the like.

### BACKGROUND OF THE INVENTION

Conventionally, as for a method for isolating a semiconductor device, there is used a LOCOS (Local Oxidation of Silicon) method for forming an element isolation film by thermal oxidation. However, the LOCOS method is disadvantageous in that miniaturization of devices is limited due to a large area of an element isolation region. Thus, as for a technique for replacing the LOCOS method, a STI (Shallow Trench Isolation) method has been developed. In the STI method, an area of an element isolation region is reduced by burying the element isolation region in a trench formed on a silicon wafer. Accordingly, the STI method can deal with miniaturization.

In the STI process, a pad oxide film and a silicon nitride film are formed in a predetermined pattern on a semiconductor substrate by a photolithography technique and, then, a trench is formed by etching using as a mask the silicon nitride film. Generally, in order to improve interface characteristics and round edges of the active region and the element isolation region, a thin oxide film is formed by oxidizing the inside of the trench. Then, a thick silicon dioxide film is formed on the entire surface of the semiconductor substrate so as to cover the trench on which the thin oxide film is formed, and an element isolation film is formed by planarization by chemical mechanical polishing while using as a stopper the silicon nitride film. In the STI method, it is difficult to bury the silicon dioxide film in the trench by using a thermal oxidation method. For that reason, a plasma CVD method or a CVD (Chemical Vapor Deposition) using TEOS (Tetra Ethyl Ortho Silicate) as a source material is performed. Recently, however, the formation of devices which requires miniaturization and low cost is carried out by a coating method such as an SOD (Spin On Dielectric) method or an SOG (Spin On Glass) method capable of burying a film in a fine trench, instead of the CVD method or the plasma CVD method.

Meanwhile, in a memory device such as a logic device, a DRAM (Dynamic Random Access Memory) or the like, a plurality of silicon dioxide films having different film thicknesses is formed as a gate oxide film of a transistor forming the memory device. For example, a relatively thick gate oxide film is used in an I/O unit or a cell, and a relatively thin oxide film is used in a core CMOS or the like. In an apparatus in which a field effect transistor is combined with a peripheral logic device, a thin gate oxide film is used in a transistor of the peripheral logic device in order to increase driving speed performance of the entire apparatus, and a thick gate oxide film having good voltage resistance is used in a transistor of a DRAM cell in consideration of a high gate voltage. Moreover, gate oxide films having different thicknesses depending on power voltages are required in a CMOS integrated circuit having a plurality of transistors operating at different power voltages.

In order to form the gate oxide films having different film thicknesses, it is required to repeat a process for forming a silicon oxide film and a wet etching process. Since, however, the element isolation film buried in the trench by the STI method is formed by a plasma CVD method or a coating method such as SOD/SOG, it is dense and defective. Therefore, the etching resistance becomes poor compared to a thermal oxide film, and the element isolation film is greatly reduced due to repetitive wet etching during the device manufacturing process. If the reduction of the element isolation film is increased, a recess is generated near the active region, which results in poor isolation function and deterioration of productivity and reliability of devices. The problem in which the element isolation film is reduced is solved in the LOCOS method for forming an element isolation film by a thermal oxidation method. However, due to the recent trend toward miniaturization, an element isolation film is formed by a CVD method or an SOD/SOG method, and the problem occurs again.

In order to avoid the reduction of the element isolation film caused by repetitive wet etching during the semiconductor device manufacturing process, it is possible to form a thick element isolation film in consideration of a reduction amount. However, in this method, the accuracy of the device design may decrease, so that the problem is not solved completely. Furthermore, the reduction of the element isolation film can be avoided or suppressed by forming a protective film (mask) on the element isolation film during processing. Since, however, a process for forming a mask is added, it is not satisfactory in terms of process efficiency and further in terms of productivity.

### SUMMARY OF THE INVENTION

In view of the above, the present invention provides a semiconductor device manufacturing method capable of manufacturing a semiconductor device while minimizing reduction of an element isolation film formed by a STI method which is cause by wet etching.

In accordance with one aspect of the present invention, there is provided a semiconductor device manufacturing method including: preparing an object to be processed which has a silicon substrate, trenches formed on the silicon substrate at a predetermined interval, element isolation oxide films buried in the trenches, and a silicon surface exposed between the element isolation oxide films; forming a sacrificial oxide film by performing a plasma oxidation process on the silicon surface; exposing the silicon surface again by removing the sacrificial oxide film by wet etching; and forming a silicon dioxide film by performing an oxidation process on the exposed silicon surface, wherein the plasma oxidation process is performed in a processing chamber of a plasma processing apparatus by using a plasma in which O(¹D₂) radicals produced by using a processing gas containing oxygen are dominant.

In accordance with another aspect of the present invention, there is provided a semiconductor device manufacturing method including: preparing an object to be processed which has a silicon substrate, trenches formed on the silicon substrate at a predetermined interval, element isolation oxide films buried in the trenches, and a silicon surface exposed between the element isolation oxide films; forming a sacrificial oxide film by oxidizing the silicon surface; exposing the silicon surface again by removing the sacrificial oxide film by wet etching; forming a silicon dioxide film by performing a plasma oxidation process on the exposed silicon surface; removing at least a portion of the silicon dioxide film by wet etching; and forming a silicon dioxide film, which is thinner than the silicon dioxide film, by oxidizing a portion of the silicon surface exposed by removing the silicon dioxide film; wherein the plasma oxidation process is performed in a processing chamber of a plasma processing apparatus by using a plasma in which O(¹D₂) radicals produced by using a processing gas containing oxygen are dominant.

In view of the above aspects of the present invention, the formation of the silicon dioxide film by plasma oxidation of the exposed silicon surface and the removal of at least a part of the silicon dioxide film by wet etching may be repeatedly performed.

Further, the oxidation process described in the one aspect of the present invention and the oxidation of the silicon surface and/or the oxidation of the portion of the silicon surface exposed by removal of the silicon dioxide film described in the another aspect of the present invention are performed in the processing chamber of the plasma processing apparatus by using the plasma in which the O(¹D₂) radicals produced by using the processing gas containing oxygen are dominant.

Furthermore, a density of the O(¹D₂) radicals of the plasma may be greater than or equal to about 1×10¹² [cm⁻³].

In the above described case, it is preferred that a pressure in the processing chamber ranges from about 1.33 Pa to 333 Pa. A ratio of the oxygen in the processing gas may range from about 0.2% to 1%. Further, the processing gas may contain hydrogen at a ratio of about 1% or less.

In view of the above aspects of the present invention, the plasma may be a microwave-excited plasma generated by exciting the processing gas by using a microwave introduced into the processing chamber through a planar antenna having a plurality of slots.

Further, during the plasma oxidation process, a high frequency power may be supplied to a mounting table on which the object to be processed is mounted.

Furthermore, the silicon surface may be oxidized, and the element isolation oxide films may be modified.

### BRIEF DESCRIPTION OF THE DRAWINGS

FIG. 1 shows a state after a CMP process in formation of a gate oxide film in accordance with a method of the present invention.

FIG. 2 is a flowchart followed by FIG. 1 and shows a state after a silicon nitride film is removed.

FIG. 3 is a flowchart followed by FIG. 2 and shows a state after a pad oxide film 107 is removed.

FIG. 4 is a flowchart followed by FIG. 3 and shows a state in which a sacrificial oxide film is formed by a plasma oxidation process.

FIG. 5 is a flowchart followed by FIG. 4 and shows a state in which the sacrificial oxide film is removed.

FIG. 6 is a flowchart followed by FIG. 5 and shows a state in which a thick gate oxide film is formed by a plasma oxidation process.

FIG. 7 is a flowchart followed by FIG. 6 and shows a state in which a mask is removed after wet etching.

FIG. 8 is a flowchart followed by FIG. 7 and shows a state in which a thin gate oxide film is formed by a plasma oxidation process.

FIG. 9 shows a state in which a sacrificial oxide film is formed by a thermal oxidation process in a comparative method.

FIG. 10 is a flowchart followed by FIG. 9 and shows a state after the sacrificial oxide film is removed.

FIG. 11 is a flowchart followed by FIG. 10 and shows a state after a thick gate oxide film is formed by a thermal oxidation method.

FIG. 12 is a flowchart followed by FIG. 11 and shows a state after a part of the gate oxide film is removed.

FIG. 13 is a flowchart followed by FIG. 12 and shows a state after a thin gate oxide film is formed by a thermal oxidation method.

FIG. 14A is a schematic cross sectional view showing an example of the plasma processing apparatus suitable for implementation of the method of the present invention.

FIG. 14B is a schematic cross sectional view showing another example of the plasma processing apparatus suitable for implementation of the method of the present invention.

FIG. 15 shows a structure of a planar antenna.

FIG. 16 explains a configuration example of a control unit.

FIG. 17 explains mechanism of a plasma oxidation process using O(¹D₂) radicals.

FIG. 18A is a graph showing relationship between a depth of an oxide film and a wet etching rate in a test 1.

FIG. 18B is a graph showing conditions selected from the conditions in the graph of FIG. 18A.

FIG. 19 is a graph showing RMS roughness of a surface of an SiO₂ film in a test 2.

FIG. 20 is a graph showing RMS roughness of a Si/SiO₂ interface in the test 2.

FIG. 21 is a graph showing a result of measurement of distribution of concentration of boron in silicon by SIMS (secondary ion mass spectrometry) in a test 3.

FIG. 22 is a graph showing relationship between a depth of an oxide film and a wet etching rate in a test 4.

### DETAILED DESCRIPTION OF THE EMBODIMENTS

Hereinafter, embodiments of the present invention will be described in detail with reference to the accompanying drawings.

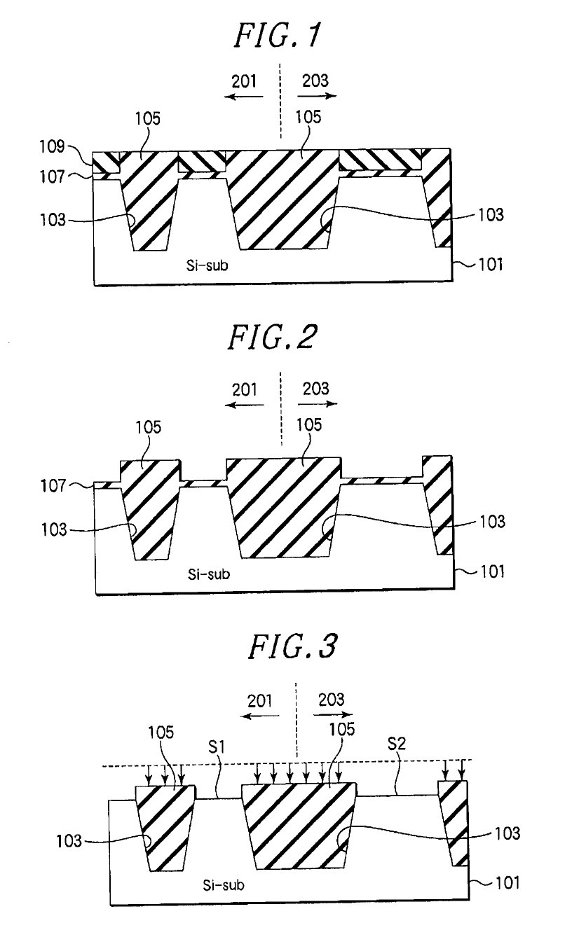

FIGS. 1 to 8 are flowcharts showing the sequence of the case where the semiconductor device manufacturing method of the present invention is applied to formation of a gate oxide film during manufacturing of a transistor as a semiconductor device. First, FIG. 1 shows a state in which a plurality of trenches 103 is formed in a silicon substrate 101 and a silicon dioxide film 105 as an element isolation film is buried in each of the trenches 103. The space between the silicon dioxide films 105 is an active region forming a transistor. In FIG. 1, two device regions divided by a dotted line in the center of FIG. 1 are illustrated. A left region and a right region respectively represent a transistor forming region 201 used for, e.g., an I/O unit, a cell or the like, and a transistor forming region 203 used for, e.g., a core CMOS or the like. The region 201 is a high-voltage transistor forming region, and the region 203 is a low-voltage transistor forming region (the terms “high voltage” and “low voltage” are relative terms).

A pad oxide film 107 is formed on the silicon substrate 101, and a silicon nitride film 109 is formed thereon. The pad oxide film 107 is an SiO₂ film which is formed to have a thickness of about 0.02 to 0.05 μm by thermal oxidation to protect a silicon surface. The silicon nitride film 109 serves as a mask for forming the trenches 103 in the silicon substrate 101 and as a stopper for planarizing the silicon dioxide film 105 by CMP.

FIG. 1 shows a state after the CMP process. Although it is not illustrated, processes performed before the CMP process are described as follows. First, the pad oxide film 107 is formed by performing a thermal oxidation process on a silicon surface of the silicon substrate 101. Next, the silicon nitride film 109 is laminated on the pad oxide film 107 by, e.g., a CVD method. Then, a photoresist film (not shown) is formed in a pattern on the silicon nitride film 109. The silicon nitride film 109, the pad oxide film 107 and the silicon substrate 101 are etched while using as a mask the photoresist film having a pattern, thereby forming the trenches 103 in the silicon substrate 101. Next, a silicon dioxide film which will serve as an element isolation film (silicon dioxide film 105) later is formed on the inside of the trenches 103 and on the silicon nitride film 109. In this process, as will be described later, the trenches 103 are buried by SOD, SOG, CVD or plasma CVD in order to deal with miniaturization. If necessary, a process for creating Si—O bonding by a thermal oxidation process or a thermal annealing process may be performed. Then, chemical mechanical polishing (CMP) is performed while using the silicon nitride film 109 as a stopper such that the silicon dioxide film remaining on the silicon oxide film 109 is removed and the silicon dioxide film 105 remains in the trenches 103. In this manner, the structure of FIG. 1 is manufactured.

The silicon dioxide film 105 serving as an element isolation film is an SOD film, an SOG film, or a film formed by CVD or plasma CVD. The SOD film/SOG film can be formed by using, e.g., polysilazane or an inorganic material obtained by a sol-gel process. More specifically, it is possible to use, e.g., Spinfil® series 400, Spinfil series 600 (AZ Electronic Material Services Ltd) or the like. The SOD material/SOG materials are buried in the trenches and then thermally oxidized under, e.g., a steam atmosphere. Accordingly, Si—O bonding is created, and SiO₂ is formed. When SiO₂ is buried in the trenches by CVD or plasma CVD, the silicon dioxide film 105 can be formed by performing thermal annealing.

FIG. 2 shows a state after the silicon nitride film 109 is removed from the state of FIG. 1. The silicon nitride film 109 can be removed by wet etching using, e.g., hot phosphate (heated phosphate solution).

Next, the pad oxide film 107 is removed by wet etching using, e.g., dilute hydrofluoric acid. FIG. 3 shows a state after the pad oxide film 107 is removed. In this process, silicon surfaces S1 and S2 are exposed by the removal of the pad oxide film 107, and the surface of the silicon dioxide film 105 as an element isolation film is etched to have a reduced film thickness. Since the pad oxide film 107 is a thermal oxide film and the silicon dioxide film 105 is an SOD film, an SOG film or a CVD film, the silicon dioxide film 105 is more easily etched than the pad oxide film 107.

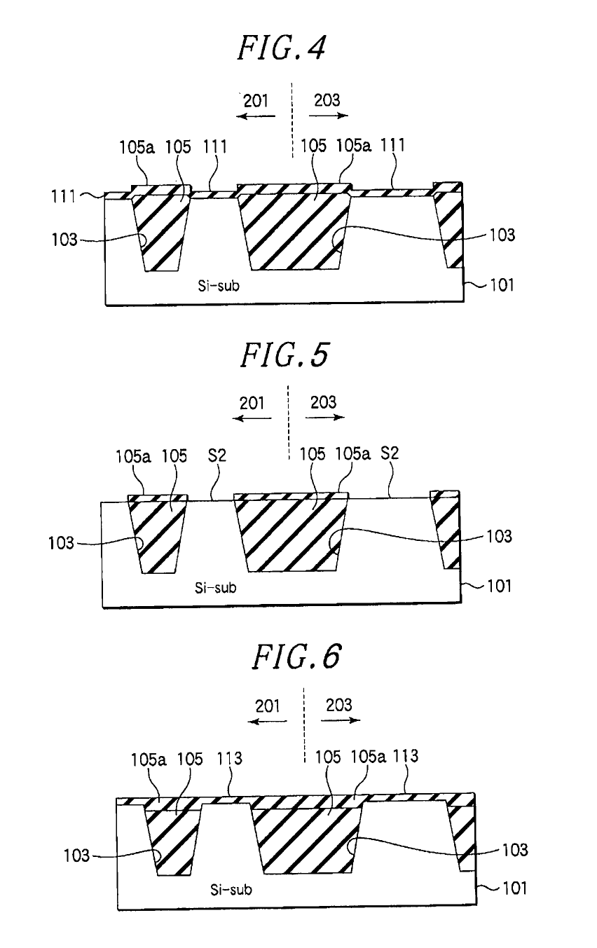

Thereafter, a sacrificial oxide film 111 is formed by oxidizing the silicon surfaces S1 and S2 in order to planarize the silicon surfaces S1 and S2. In the present invention, as will be described later, it is preferable to form the sacrificial oxide film 111 by performing a plasma oxidation process using a plasma in which O(¹D₂) radicals are dominant, and more preferable to perform a plasma oxidation process while applying a bias voltage to the silicon substrate 101 as an object to be processed. FIG. 4 shows a state in which the sacrificial oxide film 111 is formed by the plasma oxidation process. The sacrificial oxide film 111 is formed to have a thickness of, e.g., about 1 to 6 nm, and the silicon dioxide film 105 is modified from the surface to a depth of, e.g., about 3 to 200 nm, and densified. This dense modified layer near the silicon dioxide film 105 is denoted by a reference numeral ‘105a’.

Then, the sacrificial oxide film 111 is removed by wet etching using dilute hydrofluoric acid, so that the silicon surfaces S1 and S2 are exposed again. FIG. 5 shows a state in which the silicon surfaces S1 and S2 are exposed by the removal of the sacrificial oxide film 111. The silicon dioxide film 105 undergoes a plasma oxidation process and is densified. Accordingly, the modified layer 105a is formed, and the etching resistance is increased. Accordingly, the reduction of the silicon dioxide film 105 is suppressed even after the sacrificial oxide film 111 is removed. The film thickness of the modified layer 105a is slightly reduced by wet etching. In the method of the present invention, by performing the plasma oxidation process using a plasma in which O(¹D₂) radials are dominant in a part of the oxidation processes, the surface of the silicon dioxide film 105 is modified and densified. Hence, the reduction of the film by wet etching can be suppressed.

Next, in order to form a gate oxide film, a plasma oxidation process is performed again on the exposed silicon surfaces S1 and S2 in the regions 201 and 203 by using a plasma in which O(¹D₂) radicals are dominant. FIG. 6 shows a state in which a thick oxide gate oxide film 113 is formed. Here, the gate oxide film 113 is formed to have a thickness of, e.g. about 2 to 6 nm, and the modified layer 105a on the surface of the silicon dioxide film 105 is further formed. In this process, the plasma oxidation process is performed on the silicon substrate 101 as an object to be processed while applying a bias voltage thereto. Thus, the processing can be performed at a low temperature, and the silicon dioxide film 105 is modified, which is more preferable.

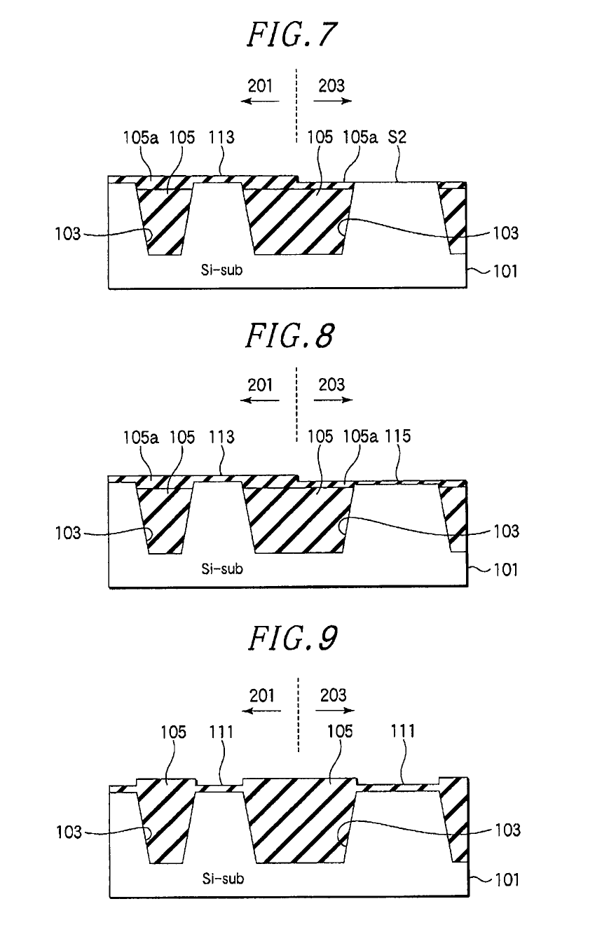

Next, the gate oxide film 113 in the region 203 is removed while leaving the gate oxide film 113 in the region 201. Here, a mask (not shown) is formed on the gate oxide film 113 of the region 201 and, then, the gate oxide film 113 in the region 203 is removed by wet etching. FIG. 7 shows a state after the wet etching (after the mask is removed). In the region 203, the silicon surface S2 is exposed by removing the gate oxide film 113. In the region 203, the modified layer 105a of the silicon dioxide film 105 is slightly reduced by etching. As a result, as schematically illustrated in FIG. 7, the film thickness of the silicon dioxide film 105 in the region 203 is reduced compared to that of the silicon dioxide film 105 in the region 101, and the surface height of the silicon dioxide film 105 is lowered. However, due to the dense modified layer 105a formed by the plasma oxidation process, the reduction amount is decreased, and a recess is not formed.

Then, a plasma oxidation process is performed again on the exposes silicon surface S2 by using a plasma in which O(¹D₂) radicals are dominant. FIG. 8 shows a state after the plasma oxidation process. Due to this plasma oxidation process, the silicon surface S2 in the region 203 is oxidized, and a thin oxide film 115 is formed to have a thickness of, e.g., about 1 to 4 nm. In the present embodiment, the reduction of the element isolation film 105 including the modified layer 105a is suppressed, so that a step or a recess is not formed between the gate oxide film 115 and the silicon dioxide film 105 adjacent thereto in the region 203. In the region 201, the modified layer 105a on the surface of the silicon oxide film 105 is further formed by performing the plasma oxidation process.

Here, a comparative method in which the sacrificial oxide film 111 and the gate oxide film of the region 201 are formed by a thermal oxidation method will be described in order to exhibit advantages of the method of the present invention. FIGS. 9 to 13 show the case in which a thermal oxidation process is performed through the same processes as those of FIGS. 1 to 8, instead of the plasma oxidation process using a plasma in which O(¹D₂) radicals are dominant. Like reference numerals will be given to like parts shown in FIGS. 1 to 8, and redundant description will be omitted.

FIG. 9 corresponding to FIG. 4 shows a state after the sacrificial oxide film 111 is formed. Here, the sacrificial oxide film 111 is formed by a thermal oxidation method, so that the silicon dioxide film 105 is also thermally oxidized. However, the surface of the silicon dioxide film 105 is not densified (a modified layer is not formed). This is because the supply of energy is not sufficient enough to cut bonds between molecules or atoms in the thermal oxidation process.

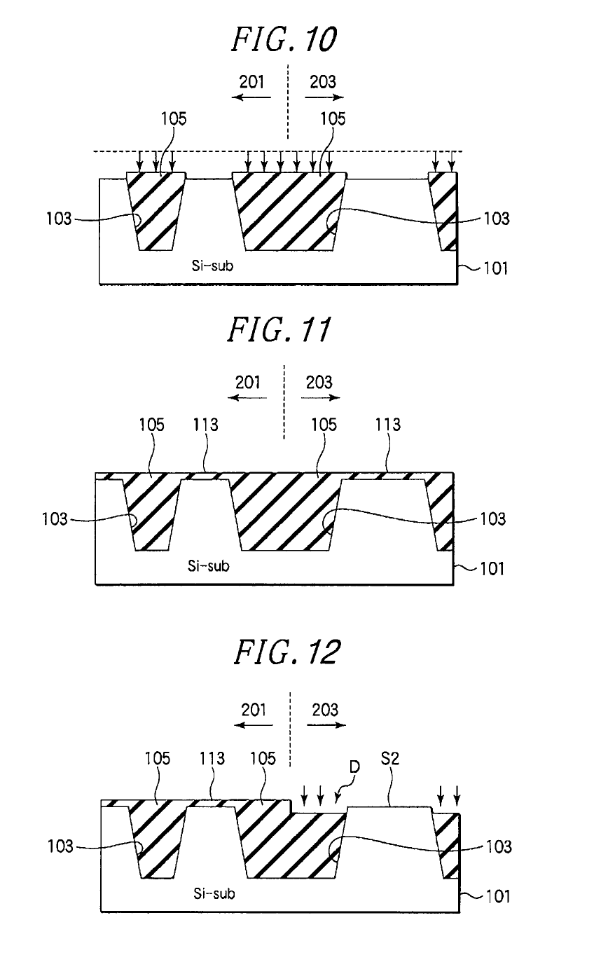

Thereafter, the sacrificial oxide film 111 is removed from the state shown in FIG. 9 by wet etching using dilute hydrofluoric acid. FIG. 10 corresponding to FIG. 5 shows a state after the sacrificial oxide film 111 is removed. Referring to the comparison between FIGS. 10 and 5, it is found that the reduction of the film thickness of the silicon dioxide film 105 in FIG. 10 is greater than that in FIG. 5. This is because the silicon dioxide film 105 as an SOD/SOG film or a CVD film having etching resistance lower than that of a thermal oxide film is greatly etched by wet etching.

FIG. 11 corresponding to FIG. 6 shows a state after the thick gate oxide film 113 is formed by a thermal oxidation method. In this process of the comparative method, the gate oxide film 113 is formed by thermal oxidation, so that the surface of the silicon dioxide film 105 is not densified. Next, a part of the thick gate oxide film 113 (only in the region 203) is removed by wet etching from the state shown in FIG. 11. In other words, a mask (not shown) is formed in the region 201, and only the region 203 is etched by dilute hydrofluoric acid. FIG. 12 corresponding to FIG. 7 shows a state where a part of the oxide film 113 (only in the region 203) is removed. Referring to FIGS. 12 and 7, it is found that the reduction of the silicon dioxide film 105 from the surface in the region 203 in FIG. 12 is larger than that in FIG. 7, and a recess D lower than the silicon surface S2 is formed. The recess D is obtained by repetitively performing wet etching on the silicon oxide film 105 having etching resistance lower than that of the thermal oxide film. The recess D inhibits post processes and deteriorates the function of isolating adjacent devices. Accordingly, the productivity and the reliability of the devices deteriorate.

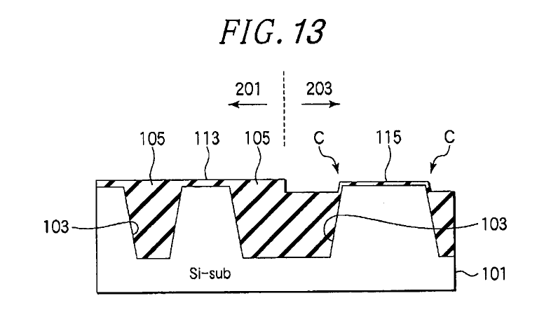

FIG. 13 corresponding to FIG. 8 shows a state after the thin gate oxide film 115 is formed by a thermal oxidation method. Referring to the comparison between FIGS. 13 and 8, the reduction of the surface the silicon dioxide film 105 from the surface in the region 203 is larger in FIG. 13 than in FIG. 8, and the surface of the silicon dioxide film 105 is lower than the silicon surface. Although the surface of the silicon oxide film 105 is coated by the gate oxide film 115, the C-shaped corner portion of the silicon forms the surface step between the gate oxide film 115 and the silicon dioxide film 105. This shape is obtained by repetitively etching the silicon dioxide film 105 having etching resistance lower than that of the thermal oxide film. The C-shaped corner portion of the silicon becomes a portion where a leakage current is generated, and deteriorates the productivity and the reliability of the devices.

In the comparative method, the formation of the recess D can be suppressed by forming a protective mask on the silicon dioxide film 105 or by performing an additional process for decreasing a wet etching rate by modifying the silicon dioxide film 105. However, this increases the number of processes. In the method of the present invention, when a silicon is oxidized, a plasma oxidation process using a plasma in which O(¹D₂) radicals is dominant is performed. Further, the oxidation of the silicon surfaces S1 and S2 and the deformation (densification) of the SiO₂ surface of the silicon dioxide film 105 can be carried out. Therefore, the formation of the recess D can be suppressed without providing an additional modification process, which leads to improvement of the processing efficiency. If necessary, the plasma oxidation process may be performed while applying a bias voltage to the object to be processed. In that case, even the deep portion of the silicon dioxide film 105 is modified, so that a more dense film can be obtained. This is because bonds between molecules or atoms can be cut by the energy supplied by radicals diffused in the film which is lager than the binding energy between the molecules or the atoms.

Since the oxidation process for forming a sacrificial oxide film or a gate oxide film is performed by using a plasma in which O(¹D₂) radicals are dominant, the process can be performed at a low temperature, and the surface of the element isolation film can be modified and densified. Therefore, the reduction of the surface of the element isolation film by wet etching can be suppressed without providing an additional modification process. Especially, the reduction of the element isolation film can be effectively suppressed by applying the plasma oxidation process using a plasma in which O(¹D₂) radicals are dominant to the process in which wet etching is repeated. Hence, the deterioration of the reliability of the semiconductor device by the reduction of the element isolation film can be prevented, and the semiconductor device can be manufactured without decreasing the processing efficiency.

Further, by performing the plasma oxidation process using a plasma in which O(¹D₂) radicals are dominant, the smoothness of the surface of the gate oxide film and the interface between the silicon and the gate oxide film can be increased. Accordingly, the mobility characteristics or the reliability can be improved, and a flickering noise (1/f noise) can be reduced. The process of the present invention which uses a plasma in which O(¹D₂) radicals are dominant can be performed at a low temperature lower than or equal to about 600° C. Therefore, the problem such as diffusion of impurities or the like hardly occurs, and design of the device and engineering of the channel can be easily carried out.

FIGS. 1 to 8 illustrate the processes for sequentially forming the gate oxide film 113 and the gate oxide film 115 having different film thicknesses. However, the method of the present invention can also be applied to processes for forming three or more gate insulating films having different film thicknesses, and the same effects can be obtained. In any case, the gate oxide film can be formed by another method such as thermal oxidation or the like, other than the plasma oxidation using a plasma in which O(¹D₂) radicals are dominant. However, it is preferable to form the gate oxide film by performing the plasma oxidation process using a plasma in which O(¹D₂) radicals are dominant, and it is more preferable to form the gate oxide film by performing the plasma oxidation process while applying a bias voltage to the silicon substrate 101 as an object to be processed.

The method of the present invention can be applied to processes including one or more steps of forming the silicon dioxide film 105 as an element isolation film and the sacrificial oxide film 111 in that order and removing the sacrificial oxide film 111 by wet etching. In the semiconductor device manufacturing process, the effect of reducing the silicon dioxide film 105 can be obtained by forming the sacrificial oxide film 111 by performing the plasma oxidation process using a plasma in which O(¹D₂) radicals are dominant (see FIGS. 4 and 5). By using a plasma in which O(¹D₂) radicals are dominant in the process for forming the sacrificial oxide film 111, the modified layer 105a is formed on the surface of the silicon dioxide film 105 as an element isolation film, and the wet etching resistance is increased. Therefore, a post oxidation process, e.g., the formation of the gate oxide film 113 or the like, may be performed by, e.g., a thermal oxidation method. When the plasma oxidation process is performed, it is preferable to apply a bias voltage to the silicon substrate 101 as an object to be processed.

Further, the method of the present invention can be applied to processes including one or more steps of forming the silicon dioxide film 105 as an element isolation film and the gate oxide film 113 in that order and removing at least a part of the gate oxide film 113 by wet etching. In the semiconductor device manufacturing process, the effect of reducing the silicon dioxide film 105 can be obtained by forming the gate oxide film 113 by performing the plasma oxidation process using a plasma in which O(¹D₂) radicals are dominant (see FIGS. 6 and 7). Especially, the method of the present invention is effective in processes in which two or more steps of oxidizing a part or all of the silicon surfaces S1 and S2 (gate oxidation process) and removing at least a part of the gate oxide film by wet etching are carried out to form a plurality of gate oxide films having different film thicknesses (see FIGS. 6 to 8). In that case, the sacrificial oxide film 111 may be formed by, e.g., a thermal oxidation method. Moreover, it is more preferable to perform the plasma oxidation process while applying a bias voltage to the silicon substrate 101 as an object to be processed.

Furthermore, the method of the present invention can be applied to processes including a step of forming the silicon dioxide film 105 as an element isolation film and the sacrificial oxide film 111 in that order and removing the sacrificial oxide film 111 by wet etching and a step of forming the gate oxide film 113 and removing at least a part of the gate oxide film 113 by wet etching. In that case, the effect of reducing the element isolation film can be obtained by forming the sacrificial oxide film 111 and the gate oxide film 113 by performing the plasma oxidation process using a plasma in which O(¹D₂) radicals are dominant (see FIGS. 4 to 7). Such effect is especially pronounced in processes in which two or more steps of oxidizing a part of or the entire silicon surface (e.g., sacrificial oxidation process, gate oxidation process) and removing at least a part of the gate oxide film (e.g., the gate oxide film 113) by wet etching are carried out to form a plurality of gate oxide films (e.g., the gate oxide films 113 and 115 or the like) having different film thicknesses (see FIGS. 4 to 8). Further, it is more preferable to perform the plasma oxidation process while applying a bias voltage to the silicon substrate 101 as an object to be processed.

In the above-described manner, the gate oxide film can be formed while suppressing the reduction of the element isolation film. The gate oxide film thus formed can be used as a gate oxide film of a transistor. In other words, the semiconductor device manufacturing method of the present invention can be suitably applied to formation of a gate insulation film in a transistor manufacturing process. In the above description, only the characteristic processes of the method of the present invention are explained, and the description of other processes is omitted. The other processes in the transistor manufacturing process, such as formation of trenches, burial of an element isolation film, planarization by CMP, formation of a well, ion implantation, formation of a gate electrode, formation of a protective film, formation of wiring, and sub-processes such as photolithography, etching, annealing, cleaning or the like can be performed by any method as long as the effect of the present invention is not adversely affected.

As described above, the formation of a recess can be avoided by applying the method of the present invention which can perform the plasma oxidation and the modification of the element isolation film to prevent etching and reduction of the element isolation film that is not an object to be removed to the processes including one or more steps of forming a silicon oxide film and removing the silicon oxide film by wet etching.

Hereinafter, a plasma processing apparatus capable of generating a plasma in which O(¹D₂) radicals are dominant which can be applied to the method of the present invention will be described.

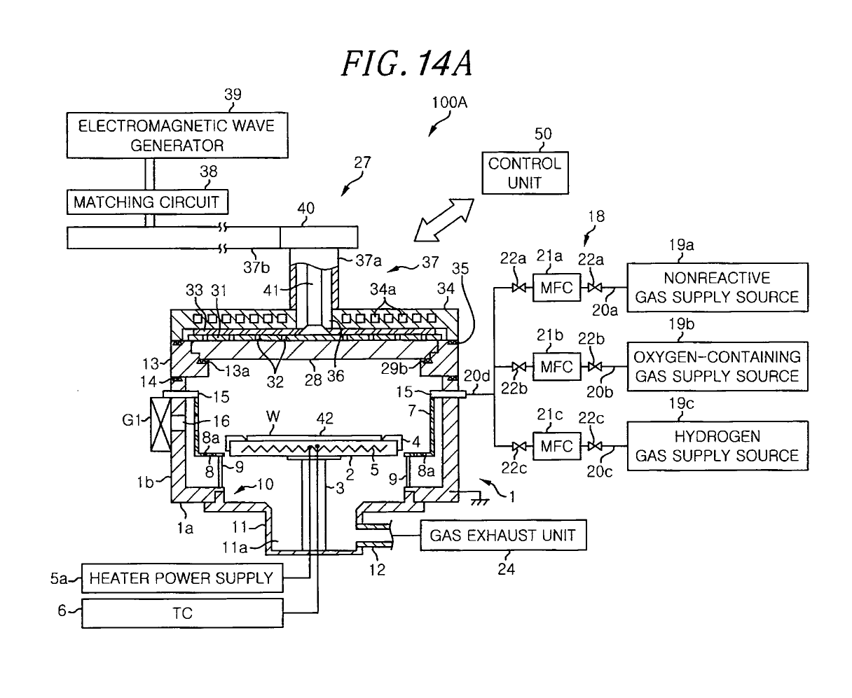

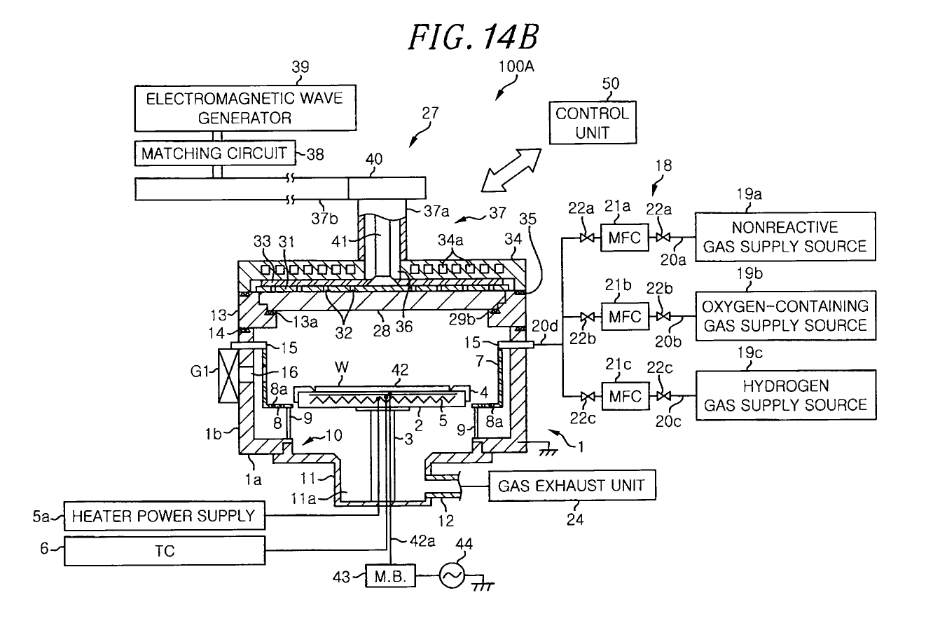

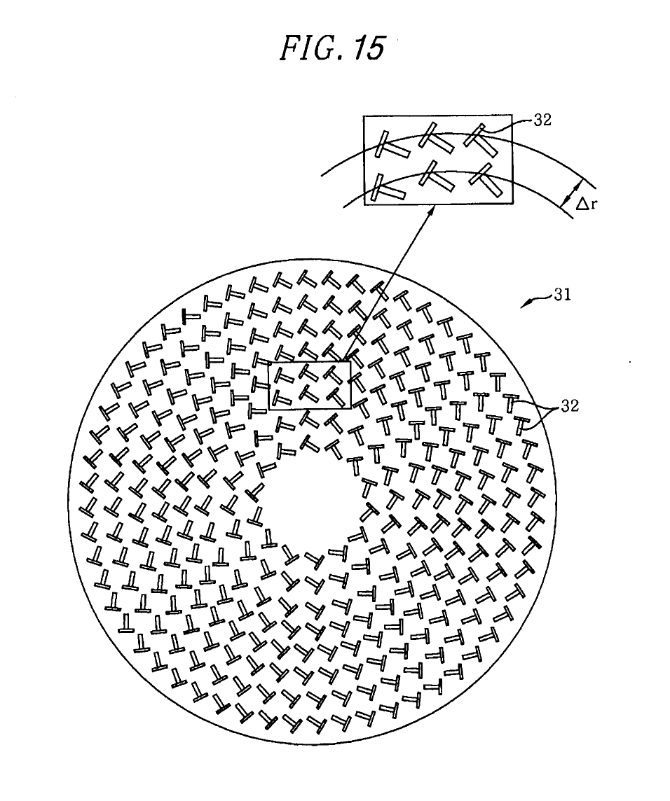

FIGS. 14A and 14B are cross sectional views schematically showing configurations of the plasma processing apparatuses 100A and 100B. FIG. 15 is a top view of a planar antenna that can be used in the plasma processing apparatuses 100A and 100B of FIGS. 14A and 14B. The difference between the plasma processing apparatus 100A of FIG. 14A and the plasma processing apparatus 100B of FIG. 14B is in that whether or not a bias application unit for applying a bias voltage to an objet to be processed is provided. Therefore, first, the common configurations of the plasma processing apparatuses 100A and 100B will be described and, then, the difference therebetween, i.e., the bias application unit of the plasma processing apparatus 100B, will be described.

Common Configuration of Plasma Processing Apparatuses 100A and 100B

The plasma processing apparatuses 100A and 100B are configured as an RLSA (Radial Line Slot Antenna) microwave plasma processing apparatus capable of generating a microwave-excited plasma of a high density and a low electron temperature by introducing a microwave into the processing chamber by using a planar antenna having a plurality of slots, particularly an RLSA. The plasma processing apparatuses 100A and 100B can perform a process using a plasma having a density of about 1×10¹⁰/cm³ to 5×10¹²/cm³ and a low electron temperature of about 0.7 eV to 2 eV. The plasma processing apparatuses 100A and 100B can be preferably used as a plasma oxidation apparatus for forming a silicon oxide film (SiO₂ film) in a manufacturing process of various semiconductor devices.

The plasma processing apparatuses 100A and 100B mainly include: a processing chamber 1; a gas supply unit 18 for supplying a gas into the processing chamber 1; a gas inlet 15 connected to the gas supply unit 18; a gas exhaust unit having a vacuum pump 24, for depressurizing and exhausting the processing chamber 1; a microwave introducing mechanism 27 serving as a plasma generating device for generating a plasma in the processing chamber 1; and a control unit 50 for controlling each component of the plasma processing apparatuses 100A and 100B. Further, the gas supply unit 18 may not be included in the components of the plasma processing apparatuses 100A and 100B. In that case, an external gas supply unit may be connected to the gas inlet 15.

The processing chamber 1 is formed by a substantially cylindrical container which is grounded. Moreover, the processing chamber 1 may be formed by a square column shaped container. The processing chamber 1 has a bottom wall 1a and a sidewall 1b made of metal such as aluminum or an alloy thereof.

The mounting table 2 for horizontally supporting a semiconductor wafer W (hereinafter, referred to as a “wafer”) as an object to be processed is provided in the processing chamber 1. The mounting table 2 is made of a material having high thermal conductivity, e.g., ceramic such as AlN or the like. The mounting table 2 is supported by a cylindrical supporting member 3 extending upwardly from a center of a bottom portion of the gas exhaust chamber 11. The supporting member 3 is made of, e.g., ceramic such as AlN or the like.

The mounting table 2 is provided with a cover ring 4 for covering an outer peripheral portion of the mounting table 2 and for guiding the wafer W. The cover ring 4 is an annular member made of quartz, AlN, Al₂O₃, SiN or the like.

A resistance heater 5 serving as a temperature control mechanism is embedded in the mounting table 2. The heater 5 is fed by a heater power source 5a to heat the mounting table 2, so that the wafer W as a substrate to be processed can be uniformly heated.

The mounting table 2 is provided with a thermocouple (TC) 6. Since a temperature of the mounting table 2 is measured by the thermocouple 6, the heating temperature of the wafer W can be controlled within a range from, e.g., a room temperature to about 900° C.

Furthermore, wafer support pins (not shown) for supporting and vertically moving the wafer W are provided at the mounting table 2. Each of the wafer support pins can be protruded from and retracted into the surface of the mounting table 2.

A cylindrical quartz liner 7 is disposed on an inner circumference of the processing chamber 1. In addition, a quartz baffle plate 8 having a plurality of gas exhaust holes 8a is annularly disposed on an outer circumferential side of the mounting table 2 so that the processing chamber 1 can be uniformly exhausted. The baffle plate 8 is supported by a plurality of supports 9.

A circular opening 10 is formed at a substantially central portion of the bottom wall la in the chamber 1. A gas exhaust chamber 11 extends downward from the bottom wall 1a and communicates with the opening. A gas exhaust line 12 is connected to the gas exhaust chamber 11, and the gas exhaust chamber 11 is connected to a vacuum pump 24 via the gas exhaust line 12.

A plate 13 having a circular opening in the center thereof is provided at an upper portion of the processing chamber 1. An inner peripheral portion of the opening protrudes inwardly (toward the inner space of the processing chamber) and thus forms an annular support portion 13a. The plate 13 has a function of a lid for opening and closing an upper opening of the processing chamber 1. The space between the plate 13 and the processing chamber 1 is airtightly sealed by a sealing member 14.

An annular gas inlet 15 is disposed at the sidewall 1b of the processing chamber 1. The gas inlet 15 is connected to a gas supply unit 18 for supplying an oxygen-containing gas or a gas for plasma excitation via a gas line 20d. The gas inlet 15 may be connected to a plurality of gas lines (pipes). Further, the gas inlet 15 may be formed in a nozzle shape or a shower shape.

Provided on the sidewall 1b of the processing chamber 1 are a loading/unloading port 16 for loading and unloading the wafer W between the plasma processing apparatuses 100A and 100B and a transfer chamber (not shown) adjacent thereto, and a gate valve G1 for opening and closing the loading/unloading port 16.

The gas supply unit 18 includes gas supply sources (e.g., a nonreactive gas supply source 19a, an oxygen-containing gas supply source 19b, and a hydrogen gas supply source 19c), lines (e.g., gas lines 20a, 20b, 20c, 20d), flow rate control units (e.g., mass flow controllers 21a, 21b, 21c), and valves (e.g., opening/closing valves 22a, 22b, 22c). Moreover, the gas supply unit 18 may have, e.g., a purge gas supply source for replacing the atmosphere in the processing chamber 1, other than the above-described gas supply sources.

As for the non-reactive gas, it is possible to use, e.g., a rare gas. As for the rare gas, it is possible to use, e.g., Ar gas, Kr gas, Xe gas, He gas or the like. Among them, it is preferable to use Ar in view of economical efficiency. Further, as for the oxygen-containing gas, it is possible to use, e.g., oxygen (O₂), water vapor (H₂O), ozone (O₃) or the like.

The nonreactive gas, the oxygen-containing gas and the hydrogen gas (if added) are supplied from the nonreactive gas supply source 19, the oxygen-containing gas supply source 19b and the hydrogen gas supply source 19c via the gas lines 20a to 20c, respectively, and join in the gas line 20d. The joined gas flows toward the gas inlet 15 connected to the gas line 20d, and then is introduced into the processing chamber 1. Each of the gas lines 20a to 20c connected to the gas supply sources is respectively provided with mass flow controllers 21a to 21c and a pair of opening/closing valves 22a to 22c disposed at an upstream and a downstream of the mass flow controllers 21a to 21c. With this configuration of the gas supply unit 18, the switching of gases to be supplied or control of gas flow rates can be performed.

The gas exhaust unit includes a vacuum pump 24. As for the vacuum pump 24, it is possible to use a high-speed vacuum pump, e.g., a turbo molecular pump or the like. As described above, the vacuum pump 24 is connected to the gas exhaust chamber 11 of the processing chamber 1 via the gas exhaust line 12. By operating the vacuum pump 24, the gas in the processing chamber 1 uniformly flows in the space 11a of the gas exhaust chamber 11, and is discharged from the space 11a to the outside via the gas exhaust line 12. Accordingly, the processing chamber 1 can be depressurized to, e.g., about 0.133 Pa, at a high speed.

Hereinafter, the configuration of the microwave introducing mechanism 27 will be described. The microwave introducing mechanism 27 mainly includes a transmitting plate 28, a planar antenna 31, a wave retardation member 33, a cover member 34, a waveguide 37, and a matching circuit 38, and an electromagnetic wave generating device 39. The microwave introducing mechanism 27 serves as a plasma generating device for generating a plasma by introducing an electromagnetic wave (microwave) into the processing chamber 1.

The transmitting plate 28 for transmitting a microwave is provided on the support portion 13a protruded from the plate 13 toward its inner peripheral portion. The transmitting plate 28 is made of a dielectric material, e.g., quartz or ceramic such as Al₂O₃, AlN or the like. The transmitting plate 28 and the support portion 13a are airtightly sealed by a sealing member 29. Hence, the processing chamber 1 is hermitically maintained.

The planar antenna 31 is provided above the transmitting plate 28 so as to face the mounting table 2. The planar antenna 31 is formed in a disc shape. However, the planar antenna 31 is not limited to the disc shape but may be of, e.g., a quadrilateral plate shape. The planar antenna 31 is engaged to the top end of the plate 13.

The planar antenna 31 is made of, e.g., a copper plate or an aluminum plate whose surface is coated with gold or silver. The planar antenna 31 has a plurality of slot-shaped microwave irradiation holes 32 for radiating a microwave. The microwave irradiation holes 32 are formed through the planar antenna 31 in a predetermined pattern.

As illustrated in FIG. 15, each of the microwave irradiation holes 32 has a thin and long rectangular shape (slot shape). Further, a pair of adjacent microwave irradiation holes 32 is typically arranged in a “T” shape. Furthermore, such pairs of the microwave irradiation holes arranged in a predetermined shape (e.g., T-shape) are arranged along concentric circular lines as a whole.

A length of each of the microwave irradiation holes 32 or an arrangement interval between the microwave irradiation holes 32 is determined by a wavelength (2 g) of a microwave. For example, the microwave irradiation holes 32 are arranged so as to be spaced apart from each other at an interval of λg/4 to λg. Referring to FIG. 15, a distance between the adjacent microwave irradiation holes 32 arranged concentrically is indicated by Δr. Each of the microwave irradiation holes 32 may have a circular shape, an arc shape or the like. Further, the microwave irradiation holes 32 may be arranged in, e.g., a spiral shape, a radial shape or the like without being limited to the concentric pattern.

A wave retardation member 33 having a dielectric constant larger than that of vacuum is provided on an upper surface of the planar antenna 31. Since a wavelength of a microwave is lengthened in vacuum, the wave retardation member 33 has a function of adjusting a plasma by shortening the wavelength of the microwave. The wave retardation member 33 may be made of, e.g., quartz, polytetrafluoroethylene resin, polyimide resin, or the like.

The planar antenna member 31 and the transmitting plate 28, and the wave retardation member 33 and the planar antenna 31 may either be in contact with each other or separated from each other. However, they are preferably in contact with each other.

The cover member 34 is disposed above the processing chamber 1 so as to cover the planar antenna 31 and the wave retardation member 33. The cover member 34 is made of a metal material such as aluminum, stainless steel, or the like. The cover member 34 and the planar antenna 31 form a flat waveguide. The upper end of the plate 13 and the cover member 34 are sealed by a sealing member 35. In addition, the cover member 34 has a cooling water channel 34a. When cooling water circulates through the cooling water channel 34a, the cover member 34, the wave retardation member 33, the planar antenna 31, and the transmitting plate 28 can be cooled. Further, the planar antenna 31 and the cover member 34 are grounded.

An opening 36 is formed at a center of an upper wall (ceiling part) of the cover member 34. One end of the waveguide 37 is connected to the opening 36. A microwave generating device 39 for generating a microwave is connected to the other end of the waveguide 37 through a matching circuit 38.

The waveguide 37 includes a coaxial waveguide 37a having a circular cross section and extending upward from the opening 36 of the cover member 34, and a horizontally-extending rectangular waveguide 37b connected to the upper end portion of the coaxial waveguide 37a via a mode transducer 40. The mode transducer 40 has a function of converting the microwave propagated in a TE mode into a TEM mode through the rectangular waveguide 37b.

An internal conductor 41 extends in the center of the coaxial waveguide 37a. The lower end portion of the internal conductor 41 is fixedly connected to the center of the planar antenna 31. With this structure, the microwaves can be efficiently and uniformly propagated into the flat waveguide formed by the cover member 34 and the planar antenna 31 in a radial direction through the inner conductive member 41 of the coaxial waveguide 37a.

With the above-described configuration of the microwave introducing mechanism 27, the microwave generated by the microwave generating device 39 is propagated to the planar antenna 31 via the waveguide 37, and then is introduced into the processing chamber 1 via the microwave irradiation holes (slots) 32 of the planar antenna 31 and the transmitting plate 28. The microwave has preferably a frequency of, e.g., 2.45 GHz, and may also have a frequency of 8.35 GHz, 1.98 GHz, or the like.

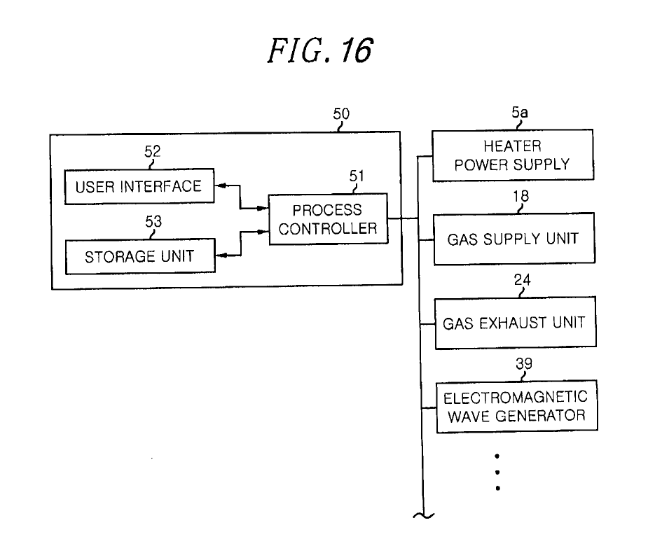

Each component of the plasma processing apparatuses 100A and 100B is connected to and controlled by a control unit 50. The control unit 50 has a computer. As shown in FIG. 16, the control unit 50 includes a process controller 51 having a CPU, a user interface 52 and a storage unit 53 connected to the process controller 51. The process controller 51 controls the components of the plasma processing apparatuses 100A and 100B (e.g., the heater power supply 5a, the gas supply unit 18, the vacuum pump 24, the microwave generating device 39 and the like) which are related to the processing conditions such as a temperature, a pressure, a gas flow rate, a microwave output and the like.

The user interface 52 has a keyboard on which a process operator inputs commands to operate the plasma processing apparatuses 100A and 100B, a display for visually displaying the operation status of the plasma processing apparatuses 100A and 100B and the like. Further, the storage unit 53 stores therein recipes including control programs (software) for implementing various processes executed by the plasma processing apparatuses 100A and 100B under the control of the process controller 51, processing condition data and the like.

Moreover, the process controller 51 executes a recipe retrieved from the storage unit 53 in response to an instruction from the user interface 52 or the like when necessary, so that a required process is performed by the plasma processing apparatuses 100A and 100B under the control of the process controller 51. Further, recipes such as the control program, the processing condition data and the like may be stored in a computer-readable storage medium, e.g., a CD-ROM, a hard disk, a flexible disk, a flash memory, a DVD, a Blu-ray disc or the like, or may be transmitted on-line from another device via, e.g., a dedicated line, whenever necessary.

Bias Application Unit

Hereinafter, a bias application unit for applying a bias to the mounting table 2 which is the characteristic configuration of the plasma processing apparatus 100B will be described. An electrode 42 is embedded in the surface of the mounting table 2 of the plasma processing apparatus 100B. The electrode 42 is connected to a high frequency power supply for bias application 44 via a matching box (M.B.) 43 by a power feed line 42a. In other words, a bias can be applied to the wafer W as a substrate by supplying a high frequency power to the electrode 42. The electrode 42, the power feed line 42a, the matching box (M.B.) 43 and the high frequency power supply 44 form the bias application unit in the plasma processing apparatus 100B. The electrode 42 may be made of a conductive material, e.g., molybdenum, tungsten or the like. The electrode 42 is formed in, e.g., a mesh shape, a lattice shape, a spiral shape, or the like.

In the plasma processing apparatuses 100A and 100B configured as described above, the plasma processing can be carried out at a low temperature of about 600° C. or less without inflicting damage to the base layer or the like. Further, the plasma processing apparatuses 100A and 100B can realize the processing uniformity in a surface of a large-sized wafer W having a diameter of, e.g., about 300 mm or above, since the uniformity of the plasma is excellent.

Hereinafter, the sequence of the plasma oxidation process performed by the plasma processing apparatuses 100A and 100B will be described. First, a gate valve G is opened, and a wafer W is loaded into the processing chamber 1 from the loading/unloading port 16. The wafer W is then mounted on the mounting table 2. Next, Ar gas and O₂ gas are introduced into the processing chamber 1 at predetermined flow rates from the nonreactive gas supply source 19a and the oxygen-containing gas supply source 19b of the gas supply unit 18 through the gas inlet 15. Then, the processing chamber 1 is maintained at a predetermined process pressure. At this time, a plasma in which a density of O(¹D₂) radical is about 1×10¹² [cm⁻³] or above is generated, and a ratio of O₂ gas in a processing gas (volume ratio) is preferably lower than or equal to, e.g., about 1%, and more preferably in the range of about 0.2% to 1%. The flow rates of Ar gas and O₂ gas can be respectively selected from the range of about 100 mL/min (sccm) to 10000 mL/min (sccm) and about 1 mL/min (sccm) to 100 mL/min (sccm) so that the ratio of the O₂ gas flow rate to the total gas flow rate can satisfy the above value.

In addition to the Ar gas and O₂ gas supplied from the nonreactive gas supply source 19a and the oxygen-containing gas supply source 19b, H₂ gas may be supplied from the hydrogen gas supply source 19c at a predetermined ratio. In that case, the ratio of H₂ gas is preferably smaller than or equal to, e.g., about 1%, at a volume ratio with respect to the entire amount of the processing gas, and more preferably in the range of about 0.01% to 1%.

The upper limit of the process pressure is preferably set to be about 333 Pa or less so that a plasma composed of O(¹D₂) radicals having a density of about 1×10¹² [cm⁻³] or above can be generated. Preferably, it is set to be about 267 Pa or less. More preferably, it is set to be about 133.3 Pa. The lower limit of the process pressure is preferably set to be about 1.33 Pa or less.

The processing temperature (the temperature of the mounting table 2) can be selected between a room temperature and about 600° C., and is preferably set in the range of, e.g., about 300° C. to 500° C.

Next, a microwave having a predetermined frequency, e.g., 2.45 GHz, generated by the microwave generating device is transmitted to the waveguide 37 via the matching circuit 38. The microwave transmitted to the waveguide 37 sequentially passes through the rectangular waveguide 37b and the coaxial waveguide 37a and then is supplied to the planar antenna 31 via the internal conductor 41. In other words, the microwave propagates in the TE mode in the rectangular waveguide 37b. Thereafter, the TE mode of the microwave is converted into the TEM mode by the mode transducer 40, and the microwave in the TEM mode propagates in the flat waveguide formed by the cover member 34 and the planar antenna 31 via the coaxial waveguide 37a. The microwave is radiated from the slot-shaped microwave irradiation holes 32 formed through the planar antenna plate toward the space above the wafer W in the processing chamber 1 through the transmitting plate 28. At this time, the output density of the microwave is preferably set to about 0.6 W or above, e.g., about 0.7 W to 3 W per area (1 cm²) of the transmitting plate 31, and more preferably set to about 0.7 W to 2.4 W. The microwave output may be selected within the range of, e.g., about 1000 W to 4000 W, in the case of processing a wafer W having a diameter of, e.g., about 200 mm or above.

Due to the microwave radiated from the planar antenna 31 into the processing chamber 1 through the transmitting plate 28, an electromagnetic field is generated in the processing chamber 1. Ar gas and O₂ gas, and H₂ gas when added, are turned into a plasma. The excited plasma has a high density ranging from about 1×10¹⁰/cm³ to 5×10¹²/cm³ and a low electron temperature of about 1.2 eV or less in the vicinity of the wafer W. Further, the plasma oxidation process is performed on the silicon surface of the wafer W by active species in the plasma, mainly by O(¹D₂) radicals. Specifically, as shown in FIGS. 2 and 3, the sacrificial oxide film 111 is formed by oxidizing the silicon surfaces S1 and S2 at a low temperature by O(¹D₂) radicals. Further, the surface of the silicon dioxide film 105 as an element isolation film is modified to a large depth by O(¹D₂) radicals. Thus, SiO₂ is highly densified, and a modified layer 105a is formed. Further, as shown in FIGS. 5 to 8, the gate oxide films 113 and 115 are formed by oxidizing the silicon surfaces S1 and S2 at a low temperature by O(¹D₂) radicals. At the same time, the surface of the silicon dioxide film 105 as an element isolation film is modified to a larger depth by O(¹D₂) radicals, and the modified layer 105a is further formed.

High Frequency Bias Voltage

In the case of using the plasma processing apparatus 100B, the high frequency power of a predetermined frequency is supplied from the high frequency power supply 44 to the electrode 42 of the mounting table 2 in the plasma oxidation process. Due to the high frequency power supplied from the high frequency power source 44, a bias voltage is applied to the wafer W, and the plasma oxidation process is accelerated while maintaining a low electron temperature of the plasma (0.7 eV to 2 eV). In other words, due to the application of the bias voltage, oxygen ions in the plasma can be attracted to the wafer W while performing modification by O(¹D₂) radicals. Hence, the oxidation rate of silicon can be increased, and the film can be modified to a large depth at a low temperature.

The frequency of the high frequency power supplied from the high frequency power supply 44 is preferably in the range of, e.g., 400 kHz to 60 MHz, and more preferably in the range of, e.g., 400 kHz to 13.5 MHz. The high frequency power is preferably supplied at a power density per area of the wafer W in the range of, e.g., 0.14 W/cm² to 1.4 W/cm², and more preferably in the range of, e.g., 0.42 W/cm² to 1.4 W/cm². When the power density is lower than 0.07 W/cm², the attractive force of ions is weak, and a high oxidation rate and a high dose amount are not obtained. On the other hand, when the power density is higher than 1.4 W/cm², the silicon dioxide film 105 as an element isolation film is damaged, and the film quality deteriorates. The high frequency power is preferably higher than or equal to about 100 W. For example, the high frequency power is preferably in the range of, e.g., 100 W to 900 W, and more preferably in the range of, e.g., 300 W to 900 W. The power density is set within the above-described range of the high frequency power.

The high frequency power supplied to the electrode 42 of the mounting table 2 has a function of attracting ions in the plasma to the wafer W while maintaining a low electron temperature of the plasma. Therefore, when the bias voltage is applied to the wafer W by supplying the high frequency power to the electrode 42 of the mounting table 2, the modification is performed by O(¹D₂) radicals and oxygen ions are attracted to the wafer. Therefore, the plasma oxidation rate and the oxygen dose amount are increased, and the film can be modified to a large depth even at a low temperature.

Effect

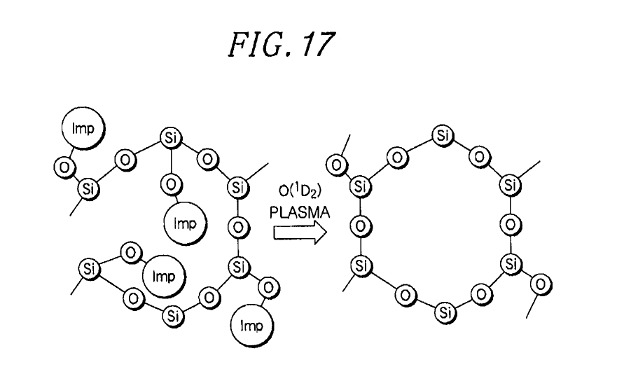

When a plasma of a processing gas containing oxygen is generated by using the plasma processing apparatuses 100A and 100B, active species in the plasma are changed depending on process pressures. In other words, under the condition of a relatively high pressure (e.g., higher than about 333 Pa and lower than or equal to about 1333 Pa) in the pressure range which can be set in the plasma processing, O2⁺ ions or O(¹D₂) radicals as active species in the plasma are decreased, and O(³P₂) radicals become dominant. Meanwhile, under the condition of a relatively low pressure (e.g., lower than or equal to about 333 Pa), O2⁺ ions or O(¹D₂) radials as active species in the plasma become dominant. The O(¹D₂) radicals generated under such conditions have a function of replacing impurities such as N, H or the like contained in the SiO₂ film with oxygen atoms. Therefore, in the oxidation process using a plasma in which O(¹D₂) radicals are dominant, the SiO₂ film is densified by replacing impurities Imp contained in the film with oxygen atoms by O(¹D₂) radicals, as shown in FIG. 17. Further, the effect of modifying the SiO₂ film is further enhanced because oxygen ions are attracted by application of a bias voltage to the silicon substrate 101 as an object to be processed. In the method of the present invention, when the silicon is oxidized, a plasma is generated under the conditions in which O(¹D₂) radicals are dominant, and the silicon surface and the SiO₂ film are processed together. Thus, the SiO₂ film can be modified to a dense SiO₂ film having less defects and regular Si—O bonds due to removal of impurities in the film. The modified SiO₂ film has wet etching resistance higher than that of an SOD film, an SOG film, or a plasma CVD film, so that the reduction thereof can be suppressed even if the wet etching is repeated in post semiconductor manufacturing process.

Hereinafter, the test result on which the present invention is based will be described.

Test 1:

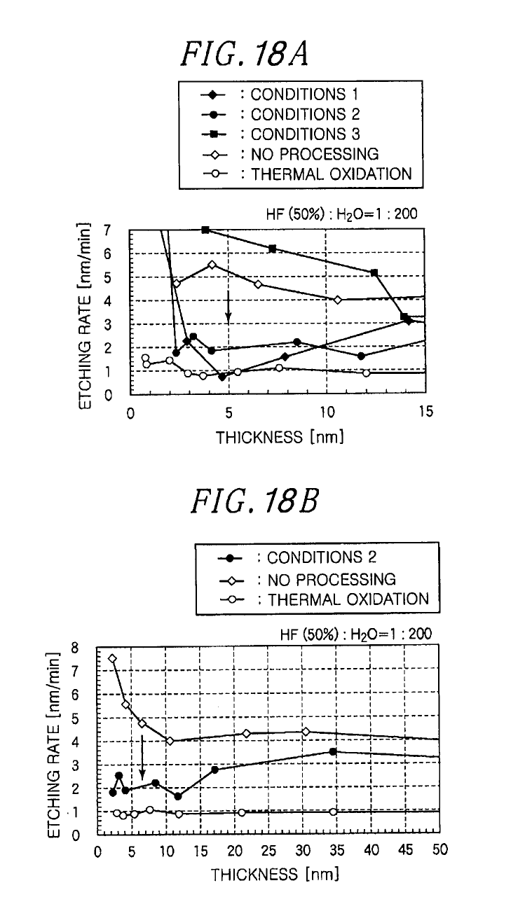

A silicon dioxide film (film thickness: 450 nm) made of polysilazane was coated by SOD and oxidized by WVG (water vapor generation). The silicon dioxide film thus formed was subjected to plasma processing by the plasma processing apparatus 100A shown in FIG. 14 under the following conditions. The silicon dioxide film subjected to the plasma processing was processed by dilute hydrofluoric acid (50% HF:H₂O=1:200), and a wet etching rate was examined. For comparison, wet etching rates of a thermal oxide film and a silicon dioxide film which were not subjected to plasma processing were examined under the same conditions. The results thereof are shown in FIGS. 18A and 18B. FIG. 18B shows conditions selected from the conditions in FIG. 18A.

[Plasma Processing Conditions 1]

Volume flow rate ratio [(O₂/Ar+O₂+H₂)×100]; 0.5 to 3%

Volume flow rate ratio [(H₂/Ar+O₂+H₂)×100]; 0.05 to 0.3%

Process pressure; 66.6 to 266 Pa (0.5 to 2 Torr)

Microwave power density; 1 to 3 W/cm² (per area 1 cm² of transmitting plate)

Temperature of mounting table 2; 400 to 500° C.

Processing time; 360 sec
(More specific conditions)

Volume flow rate ratio [(O₂/Ar+O₂+H₂)×100]; 0.8 to 1.5%

Volume flow rate ratio [(H₂/Ar+O₂+H₂)×100]; 0.08 to 0.15%

Process pressure; 106.4 to 199.5 Pa (0.8 to 1.5 Torr)

Microwave power density; 1.2 to 2.4 W/cm² (per area 1 cm² of transmitting plate)

Temperature of mounting table 2; 400 to 500° C.

Processing time; 360 sec
[Plasma Processing Conditions 2]

Volume flow rate ratio [[(O₂/Ar+O₂)×100]; 0.5 to 3%

Process pressure; 66.6 to 266 Pa (0.5 to 2 Torr)

Microwave power density; 1 to 3 W/cm² (per area 1 cm² of transmitting plate)

Temperature of mounting table 2; 400 to 500° C.

Processing time; 360 sec
(More Specific Conditions)

Volume flow rate ratio [(0₂/Ar+O₂)×100]; 0.8 to 1.5%

Process pressure; 106.4 to 199.5 Pa (0.8 to 1.5 Torr)

Microwave power density; 1.2 to 2.4 W/cm² (per area 1 cm² of transmitting plate)

Temperature of mounting table 2; 400 to 500° C.

Processing time; 360 sec
[Plasma Processing Conditions 3]

Volume flow rate ratio [(O₂/Ar+O₂+H₂)×100]; 15 to 30%

Volume flow rate ratio [(H₂/Ar+O₂+H₂)×100]; 0.05 to 0.3%

Process pressure; 239.4 Pa or more (1.8 Torr)

Microwave power density; 1 to 3 W/cm² (per area 1 cm² of transmitting plate)

Temperature of mounting table 2; 400 to 500° C.

Processing time; 360 sec
(More specific conditions)

Volume flow rate ratio [(O₂/Ar+O₂+H₂)×100]; 20 to 23%

Volume flow rate ratio [(H₂/Ar+O₂+H₂)×100]; 0.05 to 0.3%

Process pressure; 266 to 931 Pa (2 to 7 Torr)

Microwave power density; 1.2 to 2.4 W/cm² (per area 1 cm² of transmitting plate)

Temperature of mounting table 2; 400 to 500° C. Processing time; 360 sec
[Thermal Oxide Film Formation Conditions]

Atmosphere; H₂/O₂=450/900 mL/min(sccm)

Temperature; 950° C.

Pressure; 15000 Pa

As illustrated in FIGS. 18A and 18B, when the plasma processing was performed under the plasma processing conditions 1 and 2 in which O(¹D₂) radicals were dominant, the wet etching rate was greatly decreased compared to when the plasma processing was not performed or when the plasma processing was performed under the plasma processing condition 3 in which O(³P₂) radicals were dominant. Therefore, it is clear that the etching resistance can be improved by processing an SOD oxide film by using a plasma in which O(¹D₂) radicals are dominant.

Test 2:

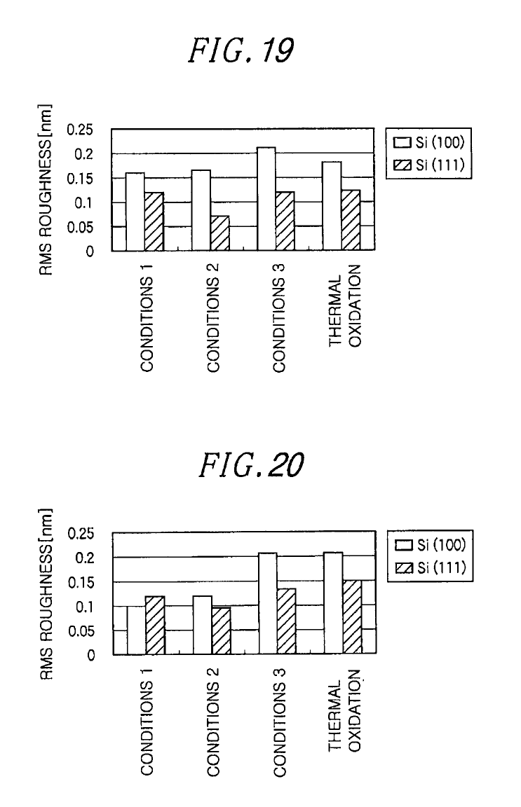

A silicon (100) surface and a silicon (111) surface were subjected to a plasma oxidation process by the plasma processing apparatus 100A shown in FIG. 14 under the following conditions 1 to 3. The RMS (average root square value) roughness of the surface of the formed SiO₂ film and that of the Si/SiO₂ interface were measured. The roughness of the surface of the SiO₂ film and that of the Si/SiO₂ interface were shown in FIGS. 19 and 20, respectively. As illustrated in FIGS. 19 and 20, in the SiO₂ film formed under the conditions 1 and 2 in which a plasma in which O(¹D₂) radicals are dominant can be generated, the RMS roughness of the surface and the Si/SiO₂ interface is decreased compared to the thermal oxide film and the smoothness is increased compared to the thermal oxide film. Therefore, when the SiO₂ film formed under the conditions 1 and 2 was used as a gate oxide film of a transistor, it is expected that the mobility characteristics and the reliability of the semiconductor device can be improved and the flickering noise (1/f noise) can be reduced.

Test 3:

A screen oxide film having a thickness of about 5 nm was formed on a silicon surface and, then, 1×10 ¹³/cm^{2 11} B+ ions were implanted at the energy of about 5 eV. Thereafter, annealing was performed at about 1000° C. for about 10 seconds, and the silicon surface was exposed by removing the screen oxide film by wet etching. In this manner, an initial sample was obtained. The initial sample was subjected to a plasma oxidation process under the above-described conditions 2 by using the plasma processing apparatus 100A shown in FIG. 14A. As a consequence, a silicon dioxide film having a thickness of about 3 nm was formed. Next, the silicon dioxide film thus formed was removed, and distribution of boron concentration in silicon was examined by SIMS (secondary ion mass spectrometry). For comparison, the initial sample was subjected to a thermal oxidation process, instead of a plasma oxidation process, under an O₂/H₂ atmosphere at about 950° C., and the distribution of boron concentration was examined. The result thereof is shown in FIG. 21.

When the initial sample was subjected to the plasma oxidation process under the above-described conditions 2 by using the plasma processing apparatus 100A, the profile of the distribution of boron concentration in silicon was substantially the same as that of the initial sample. Meanwhile, when the initial sample was subjected to a thermal oxidation process under an O₂/H₂ atmosphere at about 950° C., the profile of boron concentration in silicon was changed due to the diffusion of boron. From this, it was found that when the plasma oxidation process was performed under the conditions 2 at a relatively low temperature (about 400° C. to 500° C.) by the plasma processing apparatus 100A in the semiconductor device manufacturing process, the design of the device and the engineering of the channel can be easily carried out compared to when the thermal oxidation process was performed at a high temperature.

Test 4:

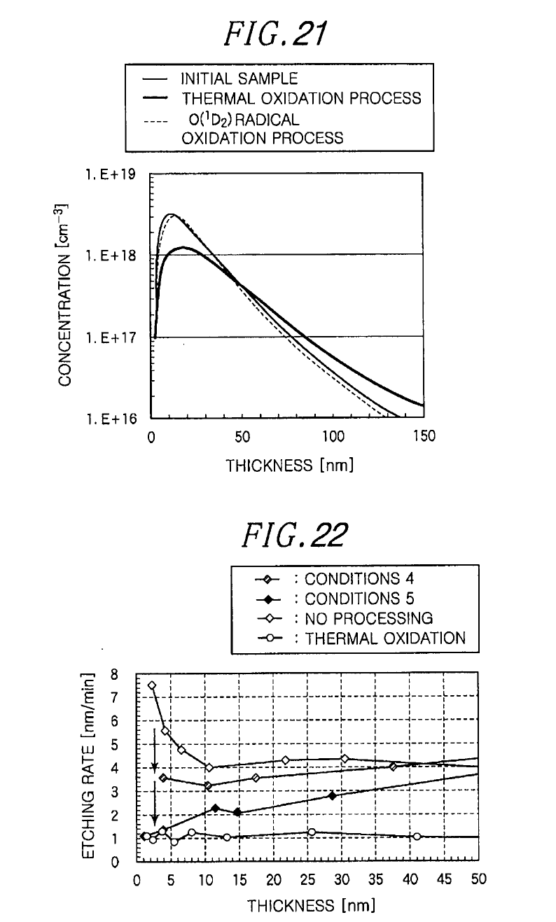

In this test, a plasma processing apparatus same as the plasma processing apparatus 100B shown in FIG. 14B was used, and the effect of bias application was examined by performing a plasma oxidation process while applying a high frequency power to the mounting table 2 on which a wafer W is mounted. A silicon dioxide film (film thickness: 450 nm) made of polysilazane was coated by SOD and oxidized by WVG. The silicon dioxide film thus formed was subjected to plasma processing under the following conditions. The silicon dioxide film subjected to the plasma processing was processed by dilute hydrofluoric acid (50% HF:H₂O=1:200), and a wet etching rate was examined. For comparison, wet etching rates of a thermal oxide film and a silicon dioxide film which were not subjected to plasma processing were examined under the same conditions. The results thereof are shown in FIG. 22.

[Plasma Processing Conditions 4]

Volume flow rate ratio [(O₂/Ar+O₂+H₂)×100]; 23%

Volume flow rate ratio [(H₂/Ar+O₂+H₂)×100]; 1.9%

Process pressure; 666.7 Pa (5 Torr)

Microwave power density; 2.4 W/cm² (per area 1 cm² of transmitting plate)

Temperature of mounting table 2; 500° C.

Frequency of high frequency power: 13.56 MHz

Power of high frequency power: 600 W (power density 0.85

W/per 1 cm² of wafer),

Processing time; 360 sec
[Plasma processing conditions 5]

Volume flow rate ratio [(O₂/Ar+O₂+H₂)×100]; 2.4%

Volume flow rate ratio [(H₂/Ar+O₂+H₂)×100]; 0.6%

Process pressure; 40 Pa (300 mTorr)

Microwave power density; 0.7 W/cm² (per 1 cm² of transmitting plate)

Temperature of mounting table 2; 500° C.

Frequency of high frequency power: 13.56 MHz

Power of high frequency power: 600 W (power density 0.85

W/per 1 cm² of wafer),

Processing time; 360 sec
[Thermal oxide film formation conditions]

Atmosphere; H₂/O₂=450/900 L/min(sccm)

Temperature; 950° C.

Pressure; 15000 Pa

Referring to FIG. 22, the wet etching rate was decreased under the conditions 4 and 5 in which the plasma oxidation was performed while applying a bias voltage to the wafer W compared to when the plasma processing was not performed. The comparison between the conditions 4 and 5 in which a bias voltage was applied to the wafer W showed that the wet etching rate was greatly decreased when the plasma processing was performed under the plasma processing condition 5 in which O(¹D₂) radicals were dominant compared to when the plasma processing was performed under the plasma processing condition 4 in which O(³P₂) radicals were dominant. Hence, it is clear that when the SOD oxide film is processed by a plasma in which O(¹D₂) radicals are dominant while applying a bias voltage to the wafer W, the film can be densely modified to a large depth even at a low temperature due to attraction of oxygen ions, and the etching resistance can be greatly improved.

As described above, the surface of the SiO₂ film can be modified and densified by performing a plasma oxidation process using a plasma in which O(¹D₂) radicals are dominant. When the plasma oxidation process is performed while applying a bias voltage to the wafer W as an object to be processed, the modification effect is enhanced by attraction of oxygen ions. Therefore, the reduction of the surface of the element isolation film by wet etching can be suppressed without performing an additional deformation process. Therefore, in a process for manufacturing a semiconductor, e.g., a transistor or the like, the deterioration of the reliability of the semiconductor device which is caused by the reduction of the element isolation film can be prevented, and the processing efficiency can be improved.

Moreover, when the plasma oxidation process using a plasma in which O(¹D₂) radicals are dominant is performed, the silicon at the interface between the gate oxide film and the silicon is oxidized by O(¹D₂) radical, which leads to increase of the smoothness of the surface of the gate oxide film and the interface between the silicon and the gate oxide film. Therefore, the mobility characteristics or the reliability can be improved, and the flickering noise (1/f noise) can be reduced. In addition, the process using a plasma in which O(¹D₂) radicals are dominant can be performed at a low temperature of about 600° C. or less. Accordingly, the problem such as diffusion of impurities or the like hardly occurs, and the convenience of device design and channel engineering is improved.

While the embodiments of the present invention have been described, the present invention can be variously modified without being limited to the above embodiments. For example, in the above-described embodiment, an RLSA-type microwave plasma processing apparatus is used for a plasma oxidation process. However, the present invention can be applied to any plasma processing apparatus for generating a plasma in which O(¹D₂) radicals are dominant. Therefore, it is possible to use another plasma processing apparatus, e.g., an ICP plasma processing apparatus, an ECR plasma processing apparatus, a surface reflected wave plasma processing apparatus, a magnetron plasma processing apparatus or the like.

The semiconductor device manufacturing method of the present invention is not limited to a transistor manufacturing process, and may also be applied to a process for repeating formation of a silicon oxide film and removal of the silicon oxide film by wet etching.

What is claimed is:

1. A semiconductor device manufacturing method comprising:
preparing an object to be processed which has a silicon substrate, trenches formed on the silicon substrate at a predetermined interval, element isolation oxide films buried in the trenches, and a silicon surface exposed between the element isolation oxide films;
forming a sacrificial oxide film by performing a plasma oxidation process on the silicon surface;
exposing the silicon surface again by removing the sacrificial oxide film by wet etching; and
forming a silicon dioxide film by performing an oxidation process on the exposed silicon surface,
wherein the plasma oxidation process is performed in a processing chamber of a plasma processing apparatus by using a plasma in which O(¹D₂) radicals produced by using a processing gas containing oxygen are dominant.

2. The semiconductor device manufacturing method of claim 1, wherein the oxidation process is performed in the processing chamber of the plasma processing apparatus by using the plasma in which the O(¹D₂) radicals produced by using the processing gas containing oxygen are dominant.

3. The semiconductor device manufacturing method of claim 1, wherein a density of the O(¹D₂) radicals of the plasma is greater than or equal to about 1×10¹² [cm⁻³].

4. The semiconductor device manufacturing method of claim 3, wherein a pressure in the processing chamber ranges from about 1.33 Pa to 333 Pa.

5. The semiconductor device manufacturing method of claim 3, wherein a ratio of the oxygen in the processing gas ranges from about 0.2% to 1%.

6. The semiconductor device manufacturing method of claim 3, wherein the processing gas contains hydrogen at a ratio of about 1% or less.

7. The semiconductor device manufacturing method of claim 3, wherein the plasma is a microwave-excited plasma generated by exciting the processing gas by using a microwave introduced into the processing chamber through a planar antenna having a plurality of slots.

8. The semiconductor device manufacturing method of claim 3, wherein during the plasma oxidation process, a high frequency power is supplied to a mounting table on which the object to be processed is mounted.

9. The semiconductor device manufacturing method of claim 1, wherein in the plasma oxidation process, the silicon surface is oxidized, and the element isolation oxide films are modified.

10. A semiconductor device manufacturing method comprising:
preparing an object to be processed which has a silicon substrate, trenches formed on the silicon substrate at a predetermined interval, element isolation oxide films buried in the trenches, and a silicon surface exposed between the element isolation oxide films;
forming a sacrificial oxide film by oxidizing the silicon surface;
exposing the silicon surface again by removing the sacrificial oxide film by wet etching;
forming a silicon dioxide film by performing a plasma oxidation process on the exposed silicon surface;
removing at least a portion of the silicon dioxide film by wet etching; and
forming a silicon dioxide film, which is thinner than the silicon dioxide film, by oxidizing a portion of the silicon surface exposed by removing the silicon dioxide film;
wherein the plasma oxidation process is performed in a processing chamber of a plasma processing apparatus by using a plasma in which O(¹D₂) radicals produced by using a processing gas containing oxygen are dominant.

11. The semiconductor device manufacturing method of claim 10, wherein the formation of the silicon dioxide film by plasma oxidation of the exposed silicon surface and the removal of at least a part of the silicon dioxide film by wet etching are repeatedly performed.

12. The semiconductor device manufacturing method of claim 10, wherein the oxidation of the silicon surface and/or the oxidation of the portion of the silicon surface exposed by removal of the silicon dioxide film are performed in the processing chamber of the plasma processing apparatus by using the plasma in which the O(¹D₂) radicals produced by using the processing gas containing oxygen are dominant.

13. The semiconductor device manufacturing method of claim 10, wherein a density of the O(¹D₂) radicals of the plasma is greater than or equal to about 1×10¹² [cm⁻³].

14. The semiconductor device manufacturing method of claim 13, wherein a pressure in the processing chamber ranges from about 1.33 Pa to 333 Pa.

15. The semiconductor device manufacturing method of claim 13, wherein a ratio of the oxygen in the processing gas ranges from about 0.2% to 1%.

16. The semiconductor device manufacturing method of claim 13, wherein the processing gas contains hydrogen at a ratio of about 1% or less.

17. The semiconductor device manufacturing method of claim 13, wherein the plasma is a microwave-excited plasma generated by exciting the processing gas by using a microwave introduced into the processing chamber through a planar antenna having a plurality of slots.

18. The semiconductor device manufacturing method of claim 13, wherein during the plasma oxidation process, a high frequency power is supplied to a mounting table on which the object to be processed is mounted.

19. The semiconductor device manufacturing method of claim 10, wherein in the plasma oxidation process, the silicon surface is oxidized, and the element isolation oxide films are modified.
